(19) United States
(12) Patent Application Publication
(10) Pub. No.: US 2023/0280430 A1
(43) Pub. Date: Sep. 7, 2023

(54) Image Reconstruction from Magnetic Resonance Measurement Data with a Trained Function

(71) Applicant: Siemens Healthcare GmbH, Erlangen (DE)

(72) Inventors: Marcel Dominik Nickel, Herzogenaurach (DE); Mario Zeller, Erlangen (DE)

(73) Assignee: Siemens Healthcare GmbH, Erlangen (DE)

(21) Appl. No.: 18/115,892

(22) Filed: Mar. 1, 2023

(30) Foreign Application Priority Data
Mar. 1, 2022 (DE) 10 2022 202 094.4

(51) Int. Cl. G01R 33/56; G01R 33/561; G06T 11/00; G06N 3/08

(52) U.S. Cl. CPC G01R 33/5608; G01R 33/5611; G06T 11/006; G06N 3/08; G06T 2210/41; G06T 2211/40

(57) ABSTRACT

A computer-implemented method for creating image data with a trained function from measurement data recorded with a magnetic resonance system may include: providing a trained reconstruction function, which receives magnetic resonance data in a dedicated form as input data, to which the trained reconstruction function is applied and in the process output data comprising image data determines image data, loading recorded measurement data, processing the recorded measurement data into processed magnetic resonance data such that the processed magnetic resonance data is present in a form which corresponds to the dedicated form of the input data, receiving the processed magnetic resonance data as input data, applying the provided trained reconstruction function to the received input data, wherein output data comprising image data is determined, and providing the output data.

### CROSS REFERENCE TO RELATED APPLICATIONS

This patent application claims priority to German Patent Application No.102022202094.4, filed Mar. 1, 2022, which is incorporated herein by reference in its entirety.

### BACKGROUND

### Field

The disclosure relates to an image reconstruction from magnetic resonance measurement data with a trained function.

### Related Art

Magnetic resonance technology (the abbreviation MR is used below for magnetic resonance) is a known technology, which can be used to generate images of the inside of an examination object. In simple terms, this is done by placing the examination object in a magnetic resonance device in a comparatively strong static, homogeneous main magnetic field, also called the B₀ field, at field strengths of 0.2 tesla to 7 tesla and higher, with the result that the nuclear spins of the object are oriented along the main magnetic field. In order to trigger nuclear spin resonances (echo signals) that are measurable as signals, radio-frequency excitation pulses (RF pulses) are irradiated into the examination object and the nuclear spin resonances produced are measured as so-called k-space data and, on the basis thereof, MR images are reconstructed or spectroscopic data is determined. For position encoding of the measurement data, rapidly switched magnetic gradient fields, known as “gradients” for short, are overlaid on the main magnetic field. A pattern that is used which defines a temporal sequence of RF pulses to be irradiated and gradients to be switched is known as a pulse sequence (scheme) or “sequence” for short. The recorded measurement data is digitized and stored as complex number values in a k-space matrix. From the k-space matrix occupied with values, an associated MR image is reconstructible, for example by means of a multi-dimensional Fourier transform.

For a specific measurement, a pulse sequence with a radio frequency (RF) pulse train to be emitted and a train to be switched in a coordinated manner therewith is to be emitted to gradients (with suitable gradients in the slice selection direction, in the phase encoding direction and in the read-out direction). Of particular importance herein for the imaging is the timing within the sequence, that is, the temporal intervals at which RF pulses and gradients follow one another. A multiplicity of control parameter values is usually defined in what is known as a measurement protocol, which is created in advance and can be retrieved for a particular measurement, for instance from a memory store, and, if applicable, can be modified by the operator locally, who can define additional control parameter values, for instance a specific slice spacing in a stack of slices to be measured, a slice thickness, etc. On the basis of all of these control parameter values, a magnetic resonance control sequence is then calculated, which is also referred to as measurement sequence, “MR sequence” (magnetic resonance sequence) or in brief only “sequence”.

With the traditional procedure, images of the inside of the object are recorded in slices. In this process a relatively thin slice, of typically between 1 and 5 mm, is excited in each case selectively. Such a selective excitation is achieved by a gradient being applied in the slice selection direction in a coordinated manner with an irradiated exciting RF pulse. Such a pulse arrangement (consisting of the exciting RF pulse and the associated gradient) makes it possible for the RF pulse to only act selectively on the area determined by the gradient and the RF pulse. In most cases, this slice selection direction runs parallel to what is known as the z-axis, the longitudinal axis of the magnetic resonance system or also to the longitudinal axis of a patient lying in the magnetic resonance system. A position encoding within a slice then takes place on the one hand by a phase encoding in a direction which is at right angles to the slice selection direction (in most cases the y-direction) and by a read-out encoding in the second direction which is at right angles to the slice selection direction (in most cases the x-direction). In this way, a two-dimensional frequency space, the so-called k-space, can be filled by entering the measured measurement data as raw data at the corresponding k-space points. An image of the slice can be produced therefrom by a two-dimensional Fourier transform.

There is also the possibility of exciting larger three-dimensional volumes and measuring the same in a 3D method. In this process it is no longer a thin slice that is excited in an excitation process, but instead a relatively thick slice (typically referred to as “slab”). However, these slabs of in most cases more than 10 mm thick must be measured once again in a spatially resolved manner in the slice selection direction when raw data is recorded. This is typically carried out by means of a second phase encoding, i.e. with this method measurements are carried out in a phase encoded manner in two directions and in a read-out encoded manner in one direction in order thus to fill a three-dimensional k-space with raw data and therefrom to generate a three-dimensional image volume by means of a 3D Fourier transform.

The method that is frequently used to generate echo signals following an excitation of the nuclear spins is the so-called spin-echo method. In the simplest case, through irradiation of at least one RF refocusing pulse following the irradiation of the RF excitation pulse, the transverse magnetization is, so to speak, “turned” so that the dephased magnetization is rephased again and thus, following a time TE denoted as the echo time following the RF excitation pulse, a so-called spin echo is generated.

The excitation and measurement of the echo signals generated are repeated following a repetition time TR (for example by switching different gradients for position encoding) until the desired number of echo signals have been measured and stored in the k-space in order to be able to map the examination object.

Among the SE sequences, in particular the TSE (“turbo spin echo”) sequences, which are also known by the names FSE (“fast spin echo”) or RARE (“Rapid Acquisition with Refocused Echoes”) sequences are widely used in clinical application. The advantage of the TSE sequences over the “simple” SE sequence is that following an RF excitation pulse, a plurality of refocusing pulses is switched and that thereby, a plurality of spin echo signals SE is also generated following an excitation. By this means, the data recording is accelerated since fewer repetitions of the sequence with different position encoding are needed to measure all the desired data. The scan time for the entire k-space in TSE sequences is thereby reduced according to the number of echo signals that are refocused and recorded following an excitation, according to the so-called “turbofactor”, as compared with conventional SE methods.

Another method of generating echo signals following an excitation of the nuclear spins is the so-called gradient echo method. In this context the dephasing and rephasing of the magnetization is not achieved by irradiating RF refocusing pulses, but instead by gradients switched following irradiation of the RF excitation pulse.

A gradient echo method, in which a train of gradient echoes is generated and read out following an RF excitation pulse in a read-out phase by alternating read-out gradients, is referred to as echo planar imaging (EPI). EPI sequences have a short acquisition time per image and are relatively robust with respect to movements of the examination object.

With EPI measurements, errors in the phase (phase errors) may occur which bring about artifacts. In particular, this may result in shifts in the phase of the measurement data for lines in the k-space with a different measurement direction, such as are typical in EPI methods. This may occur for instance on account of time inaccuracies when the gradient pulses are applied and/or when digitization occurs in the scope of recording the measurement data and/or on account of eddy current effects. Such an offset of the phase of the measurement data in adjacent lines of the k-space may result in what are known as N/2 ghost artifacts. Such an N/2 ghost artifact may occur in the MR image as a “ghost” mapping of the examination object and typically have a lower intensity than the actual mapping of the examination object and furthermore be shifted in the positive and/or negative direction with respect to the actual mapping of the examination object. A known method for correcting N/2 ghost artifacts is described in U.S. Pat. No. 6,043,651, for instance. A method for correcting phase errors caused as a result of drift effects is described in US 20120249138A1, for instance.

The diffusion imaging, during which at least one diffusion encoding of the excited echo signals takes place by switching diffusion gradients, is frequently based on the echo planar imaging (EPI), for instance. With a diffusion imaging with EPI, distortions, e.g. shears or compressions, as well as signal voids, or also possibly an attenuated fat saturation, may occur in the diffusion-weighted images on account of local B₀ inhomogeneities and residual eddy current fields. These distortions may lead to errors in the evaluated diffusion maps.

Methods are already known, which attempt to retrospectively correct or at least reduce the effects caused by the eddy currents. To this end, eddy current field maps, which reproduce the behavior of the eddy currents, are determined, for instance, on the basis of which eddy current-specific distortions are corrected in diffusion image data. However, eddy current field maps of this type require separate measurements, which have to be carried out in advance, for instance. One example of a procedure of this type is described in the article by Rohde et al. “Comprehensive approach for correction of motion and distortion in diffusion-weighted MRI”, Magn. Reson. Med. 2004, 51: pp. 103-14.

Recorded measurement data fills the k-space along k-space trajectories which correspond to a position encoding predetermined by the sequence. Reference is also made to a sampling of the k-space along k-space trajectories. A Cartesian k-space sampling, e.g. along parallel k-space lines or at k-space points distributed in a Cartesian manner, is frequently used during the recording of the measurement data. Non-Cartesian, e.g. radial, spiral or helical (WAVE) k-space trajectories for recording measurement data are however also known.

In order to shorten the duration of a recording of a complete measurement data record according to Nyquist, under specific conditions specific measurement data of the complete set may not be recorded, but instead subsequently extended. For the recording of an incomplete measurement data record, less time is needed than for a recording of a complete measurement data record. A method of this type is for instance a partial Fourier technique (PF, “partial Fourier”). With PF techniques, it is typically not the entire k-space but instead, in one k-space direction (PF direction), only one specific part of the k-space which is specified by a PF factor and further determined by symmetrical observations of the k-space that is sampled, in other words recorded or measured. The symmetry of the k-space is used in PF techniques to extend or fill the unmeasured part of the k-space with the aid of different reconstruction methods. With a method referred to as “zero-filling”, unrecorded regions of the k-space are filled with zeros or zero values. This is a very simple method which requires little computing power but does not always deliver satisfactory results.

An alternative method of extending unrecorded measurement data in PF methods uses what is known as a POCS algorithm (“Projection Onto Convex Sets”), which estimates missing, in other words unmeasured parts of the k-space of a measurement data record in an iterative process and in the process ensures data consistency with the actually measured parts of the k-space of the measurement data record, in other words actually measured k-space values. To this end, reference is made for instance to the publication “Implementation and Assessment of Diffusion-Weighted Partial Fourier Readout-Segmented Echo-Planar Imaging” by Robert Frost et. al. in Magnetic Resonance in Medicine 68:441-451 (2012). This method may result in an improved intensity or spatial resolution, but cannot always be applied reliably, for instance as a function of specific phase variations in the underlying measurement data record.

Furthermore, in order to shorten the scan time required overall for recording the measurement data or to increase the resolution, so-called parallel acquisition techniques (PAT) such as GRAPPA (“GeneRalized Autocalibrating Partially Parallel Acquisition”) or SENSE (“Sensitivity Encoding”) are used, for instance, in which, with the aid of a plurality of RF coils, only a number of measurement data items undersampled in the k-space according to the Nyquist theorem is recorded. The “missing” measurement data is extended here on the basis of sensitivity data of the RF coils used and calibration data sampled in a subregion of the k-space actually to be sampled for the measurement completely according to Nyquist from the measured measurement data. In this context, a so-called PAT acceleration factor specifies how significantly the k-space is undersampled. For instance, with a PAT acceleration factor PAT=2, half of the measurement data required according to Nyquist for a complete sampling is recorded, with a PAT acceleration factor PAT=4, a quarter etc.

Moreover, methods are known in which a number of images is recorded simultaneously. In general, these methods can be characterized in that at least during a part of the scan, transverse magnetization of at least two slices is used in a targeted manner simultaneously for the imaging process (“multi-slice imaging” or “slice multiplexing”). In contrast thereto, in the established “multi-slice imaging”, the signal is recorded from at least two slices alternately, i.e. completely independently of one another with a correspondingly longer scan time.

Known methods for this are, for example, the so-called Hadamard encoding, methods with simultaneous echo refocusing, methods with broadband data recording or methods which use parallel imaging in the slice direction. The latter methods also include, for example, the CAIPIRINHA technique as described by Breuer et al. in “Controlled Aliasing in Parallel Imaging Results in Higher Acceleration (CAIPIRINHA) for Multi-Slice Imaging”, Magnetic Resonance in Medicine 53, 2005, pp. 684-691 and the blipped CAIPIRINHA technique as described by Setsompop et al. in “Blipped-Controlled Aliasing in Parallel Imaging for Simultaneous Multislice Echo Planar Imaging With Reduced g-Factor Penalty”, Magnetic Resonance in Medicine 67, 2012, pp. 1210-1224.

In such slice multiplexing methods, a so-called multi-band RF pulse can be used in order to excite two or more slices simultaneously or otherwise manipulate them, for example to refocus or saturate them. Such a multi-band RF pulse is, for example, a multiplex of individual RF pulses which would be used for manipulation of the individual slices to be manipulated simultaneously. In order to be able to separate the resultant signals of the different slices, for example, a different phase is applied to each of the individual RF pulses before the multiplexing, for example by adding a linear phase increase, in each case, so that the slices are displaced relative to one another in the position space. By means of the multiplexing, for example, a baseband-modulated multi-band RF pulse is obtained from an addition of the pulse forms of the individual RF pulses.

As described, for example, in the aforementioned article by Setsompop et al., g-factor disadvantages can be reduced by shifts between the slices in that, for instance, gradient blips are used or the phases of the individual RF pulses are modulated accordingly. As likewise described in the aforementioned article by Setsompop et al., but also already in the aforementioned article by Breuer et al., the signals of the simultaneously excited or otherwise manipulated slices can firstly be grouped together like signals from only one slice in order then to be separated in the subsequent processing by a parallel reconstruction method, for example a (slice-)GRAPPA method (GRAPPA: “GeneRalized Autocalibrating Partial Parallel Acquisition”) or a SENSE method (SENSE: Sensitivity encoding).

Another possibility for accelerating the imaging in magnetic resonance is the use of so-called “compressed sensing” (CS). This involves an undersampling technique which uses special trajectories in the k-space which enable a randomized or pseudorandomized sampling pattern of the k-space. Through the use of such a randomization technique, convolution artifacts are “blurred” such that they act like image noise in the magnetic resonance images.

As of late, trained functions, which comprise neural networks, are also used to improve the reconstruction of image data from measurement data recorded in an accelerated manner by means of a magnetic resonance system. For instance, in the article by Hammernik et al. “Systematic evaluation of iterative deep neural networks for fast parallel MRI reconstruction with sensitivity-weighted coil combination”, Magn. Reson. Med. 86: pp. 1859-1872, 2021, unrolled variational neural networks are described, which enable a reconstruction of measurement data recorded by means of a PAT technique in image data while simultaneously denoising the image data. The simultaneous reconstruction and denoising by a neural network means that the resultant image data creates a natural impression despite comparatively high PAT acceleration factors, as a result of which the image quality is improved compared with image data reconstructed with conventional reconstruction techniques.

Typical unrolled and/or variational neural networks such as those described in the cited article by Hammernik et al. have alternating steps for data consistency assurance and for image regulation, wherein in most cases the image regulation is carried out by a U-shaped neural network, in particular a U net, also known as down-up network, and the data consistency assurance by gradients of a data consistency term, which comprises a signal model, which relates the reconstructed image data to the measurement data recorded in the k-space.

In general, a trained function maps cognitive functions which associate humans with human brains. By means of training on the basis of training data (machine learning), the trained function is able to adapt to new circumstances and to detect and extrapolate patterns.

In general, parameters can be adapted to a trained function by means of training. In particular, supervised learning, semi-supervised learning, unsupervised learning, reinforcement learning and/or active learning can be used. In addition, representation learning (also known as “feature learning”) can also be used. In particular, the parameters of the trained functions can be adapted, in particular, iteratively by way of a plurality of training steps.

Trained functions comprising neural networks used in image reconstruction are in most cases trained by training processes with supervised learning with pairs of training input data and associated training output data. Here enormous quantities of training input and output data, e.g. more than 10000 pairs of training input and output data, are required in order to train an individual neural network. The trained functions are therefore fixed to a dedicated form which corresponds to a form of the training input data. Any changes in form of the input data, e.g. also changes to content, type and/or a possible preprocessing, regularly result in the trained function having to be trained again for the changed shape or even the trained function itself having to be adjusted.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic flow chart of a method according to an exemplary embodiment of the present disclosure.

FIGS. 2-7 show examples for measurement data recorded in the k-space and associated processed magnetic resonance data, according to exemplary embodiments of the present disclosure.

FIG. 8 shows an image creation facility according to an exemplary embodiment of the present disclosure.

FIG. 9 shows a magnetic resonance system according to an exemplary embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to enable image data to be created from measurement data recorded with a magnetic resonance system having a trained function with an increased flexibility with respect to the form of the recorded measurement data.

The object is achieved by a method for creating image data from measurement data recorded with a magnetic resonance system, an image creation facility, a magnetic resonance system, a computer program, and an electronically readable data carrier, according to exemplary embodiments of the present disclosure.

A computer-implemented method, according to an exemplary embodiment, for creating image data with a trained function from measurement data recorded with a magnetic resonance system may include:
providing a trained reconstruction function, which receives magnetic resonance data in a dedicated form as input data, to which the trained reconstruction function is applied and in the process output data comprising image data determines image data,
loading recorded measurement data,
processing the recorded measurement data into processed magnetic resonance data such that the processed magnetic resonance data is present in a form which corresponds to the dedicated form of the input data,
receiving the processed magnetic resonance data as input data,
applying the provided trained reconstruction function to the received input data, wherein output data comprising image data is determined, and
providing the output data.

By means of the inventive processing of recorded measurement data in processed magnetic resonance data such that the processed magnetic resonance data is present in a form which corresponds to the dedicated form of input data of an existing (finished) trained reconstruction function and is thus compatible with the trained reconstruction function, the trained reconstruction function can be applied to input data which is based on measurement data recorded in a variety of ways in terms of its recording form. An expensive (renewed) training or reconfiguration of the trained reconstruction function for the recorded measurement data with different types of forms as the form dedicated to the trained reconstruction function can be omitted.

The disclosure also relates to an image creation facility. The image creation facility according to an exemplary embodiment may include a processing facility configured to process measurement data recorded using a magnetic resonance system into processed magnetic resonance data, which exists in a form which corresponds to a dedicated form of input data of a trained reconstruction function, having
a first processing interface configured to receive recorded measurement data,
a processing unit (processor) configured to apply processing steps, which transform the received recorded measurement data into a form which corresponds to the dedicated form,
a second processing interface configured to provide the processed magnetic resonance data; and
   a reconstruction facility configured to create image data, having
a first interface configured to receive processed magnetic resonance data created with the processing facility as input data,
a reconstruction unit (recontructor) configured to apply the trained reconstruction function to the input data, wherein output data comprising image data is determined, and
a second interface configured to provide the output data.

In an exemplary embodiment, the image creation facility, may include at least one processor and/or at least one storage means is embodied to carry out the inventive reconstruction method. All embodiments relating to the inventive method can be transferred analogously to the inventive image creation facility with which the already cited advantages can thus be obtained.

The image creation facility can naturally be implemented for instance also as part of an evaluation facility for evaluating measurement data recorded with a magnetic resonance system. The image creation facility can also be used for instance as part of a controller of a magnetic resonance system in order to be used in particular in the postprocessing of recorded measurement data. Other embodiments are of course conceivable.

A magnetic resonance system according to the disclosure may comprise a magnet unit, a gradient unit, a radio frequency unit and a controller embodied for carrying out a method according to the disclosure with an image creation facility.

A computer program according to the disclosure is directly loadable into a memory store of a computing facility, in particular an image creation facility, and has program means in order to carry out the steps of an inventive method when the computer program is executed on the computing facility. The computer program can be stored on an electronically readable data carrier according to the disclosure which therefore comprises control information stored thereon, which comprises the at least one computer program according to the disclosure and is configured, on use of the data carrier in a computing facility, to cause said control information to carry out the inventive method. The data carrier can be, in particular, a non-transient data carrier, for example, a CD-ROM or a USB stick.

The advantages and embodiments specified in respect of the method and/or the comparison facility apply analogously also to the magnetic resonance system, the computer program product and the electronically readable data carrier. Features, advantages and variants described for embodiments are applicable to other embodiments. In other words, embodiments directed at apparatuses/units can be improved by features which were cited with respect to the method.

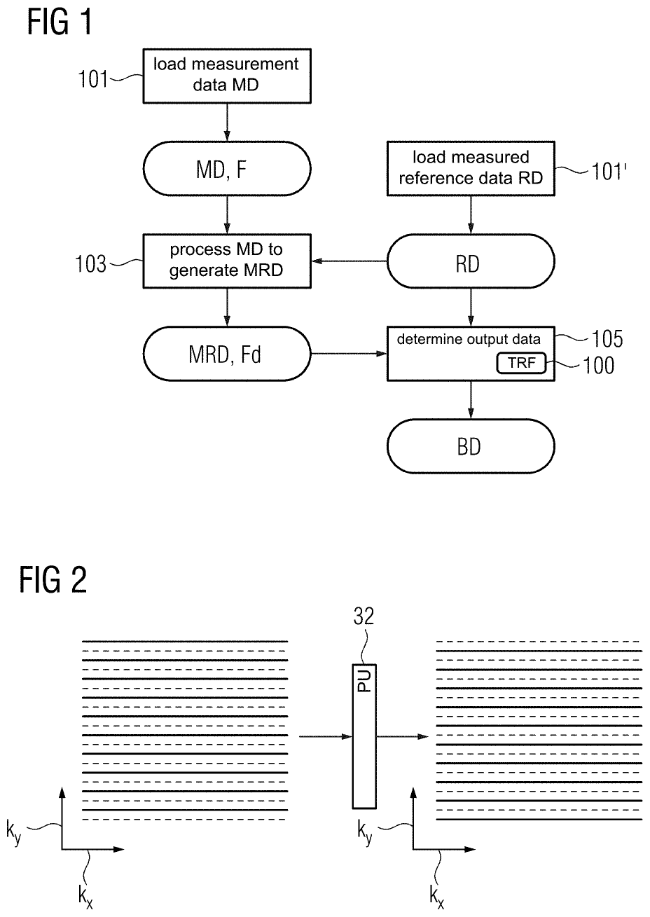

FIG. 1 shows a schematic flow chart of a computer-implemented method according to the disclosure for creating image data with a trained function from measurement data recorded with a magnetic resonance system.

A trained reconstruction function 100 is provided, which receives magnetic resonance data MRD in a dedicated form Fd as input data, to which the trained reconstruction function 100 is applied and in the process output data comprising image data BD is determined.

A reconstruction function 100 comprising a variational and/or unrolled neural network and/or a U-shaped neural network, e.g. a U-net, can be provided and used as a trained reconstruction function 100. A trained reconstruction function described in the already cited article by Hammernik et al. for reconstructing magnetic resonance data recorded in an undersampled manner by means of PAT method into image data can be provided and used as a trained reconstruction function 100.

The dedicated form Fd of the magnetic resonance data MRD can comprise for instance specifications which fix the dedicated form Fd. Specifications of this type can reflect specifications for a sampling pattern with which the magnetic resonance data fills the k-space, in particular a dimensionality of the filled k-space and/or used k-space trajectories, specifications for an undersampling factor, with which the magnetic resonance data undersample the k-space,

specifications for a number of slices for which the magnetic resonance data contains information, and/or
specifications for admissible phase errors contained in the magnetic resonance data.

Recorded measurement data MD is loaded (Block 101), wherein the recorded measurement data MD exists in a recording form F, which reflects the manner in which the recorded measurement data MD has been recorded.

The recorded measurement data MD is processed in processed magnetic resonance data MRD such that the processed magnetic resonance data MRD exists in a form which corresponds to the dedicated form Fd of the input data (Block 103).

The processing of recorded measurement data MD may comprise determining a recording form F, in which the recorded measurement data MD has been recorded and is now present. This can also take place in that when the recorded measurement data MD is loaded, its recording form F is also transferred. It is also conceivable however for the determination of the recording form F to take place by analyzing the loaded recorded measurement data MD.

The processing of recorded measurement data MD may comprise processing steps, which are selected on the basis of a recording form F, in which the recorded measurement data MD exists, and the dedicated form Fd of the magnetic resonance data MRD received as input data from the trained reconstruction function 100 is selected such that they transfer the recorded measurement data MD from its recording form F into magnetic resonance data MRD which exists in the dedicated form Fd.

The processing of recorded measurement data MD may comprise applying different methods for processing measurement data MD recorded with a magnetic resonance system. For instance, the processing of recorded measurement data MD may comprise applying a regridding method, a slice selection method, in particular a sliceGRAPPA method, a Fourier transform into the image space, a Fourier transform of data present in the image space into the k-space, a PAT method, in particular a GRAPPA or a SENSE method, a correction method, in particular a phase correction method, and/or a compressed sensing method.

In order to illustrate the principle of processing the recorded measurement data MD, a selection of examples of possible measurement data MD recorded in the k-space and associated processed magnetic resonance data MRD is explained further below on the basis of the FIGS. 2 to 7.

The processed magnetic resonance data is received as input data from the provided trained reconstruction function 100, which is applied to the thus received input data, wherein output data comprising image data BD is determined and provided (Block 105).

The provided output data can be displayed on an input/output facility I/O for instance or also stored in a memory store.

Furthermore, measured reference data RD can be loaded (Block 101′), which is considered with the processing of measured measurement data MD and/or e.g. with a data consistency assurance included in the trained reconstruction function 100 and/or when the trained reconstruction function 100 receives input data in the form of undersampled magnetic resonance data MRD, in a reconstruction of image data BD which is included in the trained reconstruction function 100. Reference data RD of this type can be for instance coil sensitivity data or calibration data, such as is used in PAT methods and slice separation methods such as sliceGRAPPA or for data consistency checks. Whether, and if so which, reference data RD is loaded therefore depends both on the recording form F, in which the loaded recorded measurement data MD exists and/or on the dedicated form Fd in which the input data is to exist.

FIG. 2 shows a first example of possible measurement data MD recorded in the k-space (shown on the left), which is processed into associated processed magnetic resonance data MRD (shown on the right) e.g. by a processing unit 32 of an image creation facility 15 explained in more detail in respect of FIG. 8.

The measurement data MD recorded and shown on the left is present in the k-space in the ky-kx plane, wherein continuous lines represent recorded k-space lines and dashed lines represent unrecorded k-space lines, so that in the example each second k-space line has been recorded. The recorded measurement data MD in the example in FIG. 2 is therefore present in a two-dimensional recording form F which corresponds to a PAT technique with a PAT factor PAT=2.

The processed magnetic resonance data MRD shown on the right is present in the dedicated form Fd, in which a provided trained reconstruction function receives input data. The dedicated form Fd is however also a two-dimensional form which corresponds to a PAT technique with a PAT factor PAT=2, however with other recorded k-space positions (sampling pattern) and/or different phase variation of the undersampling compared with the recording form F.

The processing of measurement data MD recorded in this way into desired processed magnetic resonance data MRD can comprise e.g. a phase correction and/or a k-space position correction which transforms the recorded measurement data MD from its recording form in processed magnetic resonance data MRD into the dedicated form. A PAT method such as e.g. GRAPPA or SENSE can also be used here.

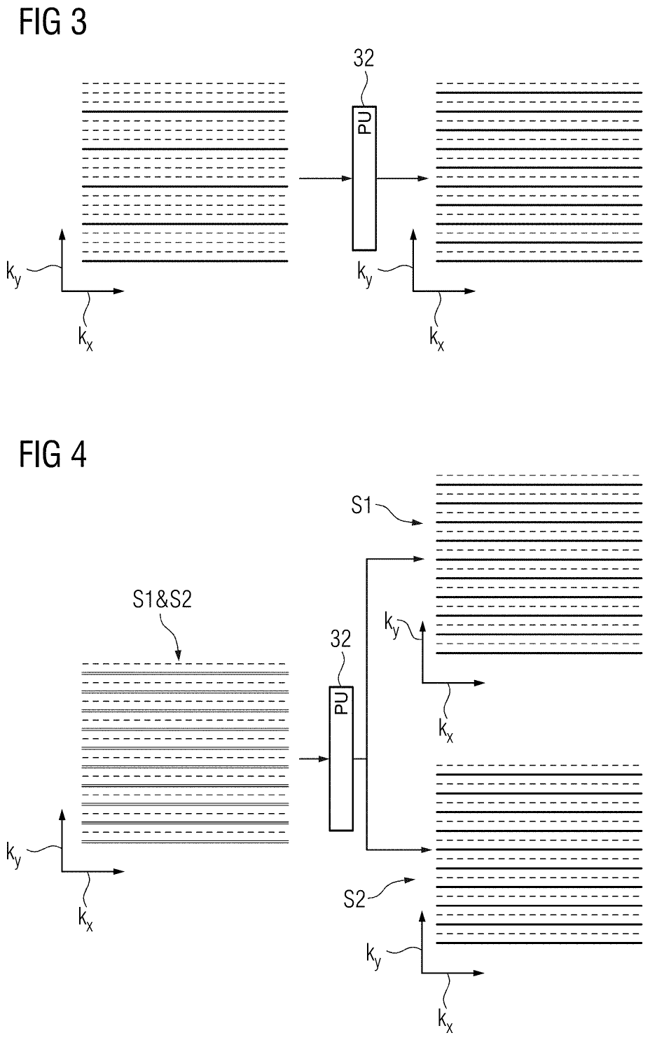

In the following examples of FIGS. 3 to 7, processed magnetic resonance data MRD is accepted in each case in a same dedicated form. This is not to be read as restrictive but should instead only be understood as a possible example.

FIG. 3 shows a further example of possible measurement data MD recorded in the k-space (shown on the left), which is processed for instance into the associated processed magnetic resonance data MRD (shown on the right) by a processing unit 32 of an image creation facility 15 explained in more detail with respect to FIG. 8.

In this example, the recorded measurement data MD shown to the left is present again in the k-space in the ky-kx plane, wherein continuous lines represent recorded k-space lines and dashed lines represent unrecorded k-space lines, so that each fourth k-space line has been recorded. The recorded measurement data MD in the example of FIG. 3 is therefore present in a two-dimensional recording form F which corresponds to a PAT technique with PAT factor PAT=4.

The processed magnetic resonance data MRD which is shown on the right is present as described above in a two-dimensional dedicated form Fd which corresponds to a PAT technique with PAT factor PAT=2. The recording form F of the recorded measurement data MD and the dedicated form Fd of the processed magnetic resonance data MRD therefore differs in particular in terms of its undersampling factor.

The processing of such recorded measurement data MD into desired processed magnetic resonance data MRD can comprise e.g. an application of a PAT method such as e.g. GRAPPA or SENSE, which extends the magnetic resonance data which is missing for the dedicated form Fd.

FIG. 4 shows a further example of possible measurement data MD recorded in the k-space (shown on the left), which is processed, for instance, into associated processed magnetic resonance data MRD (shown on the right) by a processing unit 32 of an image creation facility 15 explained in more detail with respect to FIG. 8.

In this example, the recorded measurement data MD shown on the left is present again in the k-space in the ky-kx plane, wherein continuous lines represent recorded k-space lines and dashed lines represent unrecorded k-space lines, so that each second k-space line has been recorded. The recorded measurement data MD in the example of FIG. 4 is therefore present in a two-dimensional recording form F which corresponds to a PAT technique with PAT factor PAT=2. Moreover, the recorded measurement data has been recorded in this example using an SMS technology, for instance, so that the recorded measurement data MD is measurement data MD recorded in collapsed form from a number of, in this case two, slices S1 & S1.

The processed magnetic resonance data MRD which is shown on the right is present as described above in a two-dimensional dedicated form Fd for individual slices S1, S2 which corresponds to a PAT technique with PAT factor PAT=2. The recording form F of the recorded measurement data MD and the dedicated form Fd of the processed magnetic resonance data MRD therefore differs in particular in the respective number of slices for which the magnetic resonance data contains information.

The processing of such recorded measurement data MD into desired processed magnetic resonance data MRD can comprise e.g. an application of a slice separation method known in SMS techniques such as e.g. sliceGRAPPA, which separates the recorded measurement data MD for the dedicated form Fd into desired magnetic resonance data of individual slices.

FIG. 5 shows a further example of possible measurement data MD recorded in the k-space (shown on the left), which is processed for instance into associated processed magnetic resonance data MRD (shown on the right) by a processing unit 32 of an image creation facility 15 explained in more detail with respect to FIG. 8.

In this example, the measurement data MD recorded and shown on the left is present again in the k-space in the ky-kx plane, wherein continuous lines represent recorded k-space lines and dashed lines represent unrecorded k-space lines, so that each k-space line distributed irregularly has been recorded. The recorded measurement data MD in the example in FIG. 5 is therefore present in a two-dimensional recording form F which corresponds to a special PAT technique or a compressed-sensing technique.

The processed magnetic resonance data MRD which is shown on the right is present as described above in a two-dimensional dedicated form Fd which corresponds to a PAT technique with PAT factor PAT=2. The recording form F of the recorded measurement data MD and the dedicated form Fd of the processed magnetic resonance data MRD therefore differs in particular in the respective density of the k-space sampling (sampling pattern).

The processing of such recorded measurement data MD into desired processed magnetic resonance data MRD can comprise e.g. an application of a PAT method such as e.g. GRAPPA or SENSE or a compressed sensing method, which delivers the processed magnetic resonance data desired for the dedicated form Fd.

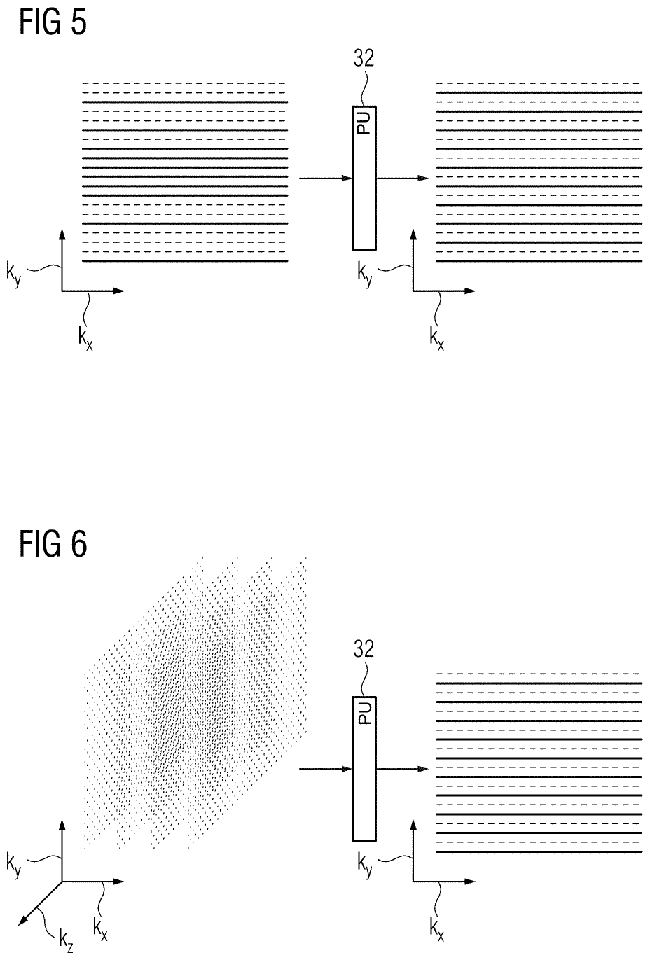

FIG. 6 shows a further example of possible measurement data MD recorded in the k-space (shown on the left), which is processed, for instance, into associated processed magnetic resonance data MRD (shown on the right) by a processing unit 32 of an image creation facility 15 which is explained in more detail with respect to FIG. 8.

In this example, the recorded measurement data MD shown to the left is present in the three-dimensional k-space (ky-kx-kz) so that a three-dimensional set of k-space data has been recorded as measurement data MD. The recorded measurement data MD in the example in FIG. 6 is therefore present in a three-dimensional recording form F.

The processed magnetic resonance data MRD which is shown on the right is present as described above in a two-dimensional dedicated form Fd which corresponds to a PAT technique with PAT factor PAT=2. The recording form F of the recorded measurement data MD and the dedicated form Fd of the processed magnetic resonance data MRD therefore differs in particular in the respective dimensionality of the k-space sampling.

The processing of such recorded measurement data MD into the desired processed magnetic resonance data MRD can comprise e.g. an application of a Fourier transform in a completely recorded direction kx, ky, kz or in particular if a complete sampling is not carried out in any direction kx, ky, kz, can comprise a PAT method such as GRAPPA or SENSE for completing the recorded measurement data MD in one direction kx, ky, kz and then Fourier transform in this direction which supplies the processed magnetic resonance desired for the dedicated form Fd and present in the two-dimensional form.

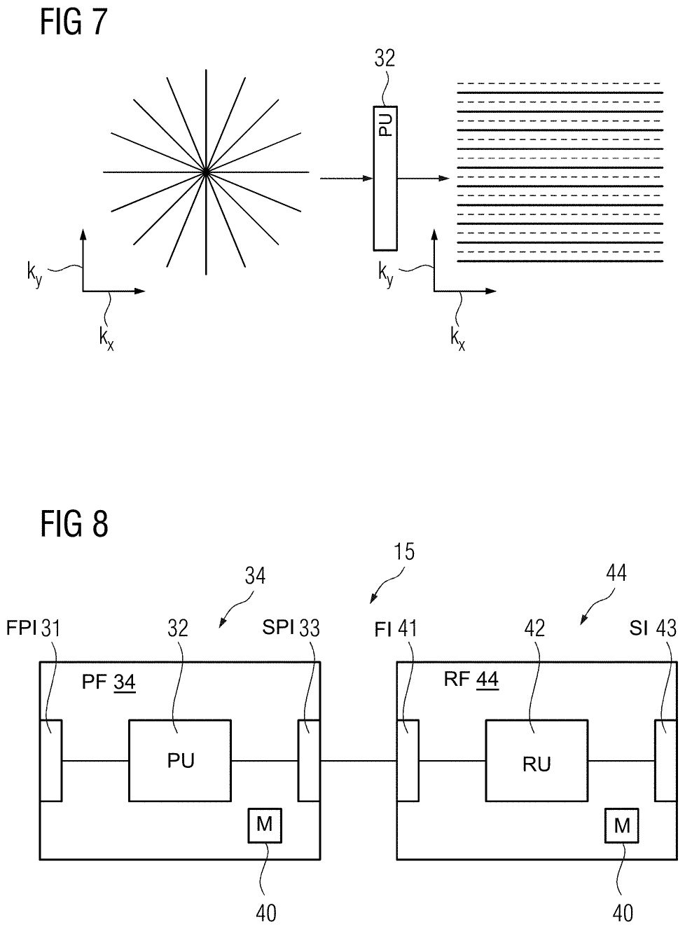

FIG. 7 shows a further example of possible measurement data MD recorded in the k-space (shown on the left), which is processed, for instance, into associated processed magnetic resonance data MRD (shown on the right) by a processing unit 32 of an image creation facility 15 shown in more detail in respect of FIG. 8.

In this example, the measurement data MD recorded and shown on the left is present again in the k-space in the ky-kx plane, wherein continuous lines represent recorded k-space lines so that a radial sampling pattern has been used. The recorded measurement data MD in the example in FIG. 7 is therefore present in a two-dimensional recording form F which corresponds to a radial sampling.

The processed magnetic resonance data MRD, which is shown on the right, is present as described above in a two-dimensional dedicated form Fd which corresponds to a PAT technique with PAT factor PAT=2. The recording form F of the recorded measurement data MD and the dedicated form Fd of the processed magnetic resonance data MRD therefore differ in particular in the k-space trajectories used.

The processing of such recorded measurement data MD into desired processed magnetic resonance data MRD can comprise e.g. an application of a regridding method, which brings the measurement data MD present in the recording form F and recorded with non-Cartesian sampling patterns into a Cartesian distribution of the processed magnetic resonance data MRD in the k-space, which is desired for the dedicated form Fd.

Further examples, not shown, can have different phase errors which are present in the recorded measurement data MD and are permissible in dedicated form in the processed magnetic resonance data MRD.

For instance, if the recorded measurement data MD has been recorded using an EPI technique, the processing of the recorded measurement data can comprise a phase correction, e.g. a correction of N/2 ghosts according to U.S. Pat. No. 6,043,651 already cited above and/or a drift correction, e.g. according to US20120249138A1 also already cited above.

Further possible correction methods, which can be included in the processing of recorded measurement data MD in processed magnetic resonance data MRD are for instance respiration compensation correction methods, eddy current correction methods (when EPI recording techniques or also TSE or TGSE recording techniques are used) or also corrections of ghost artifacts of a higher order, such as e.g. dual polarity GRAPPA methods, such as are described for instance in the article by Hoge et al. “Dual polarity GRAPPA for simultaneous reconstruction and ghost correction of echo planar imaging data”, Magn. Reson. Med. 76: pp. 32-44, 2016.

In summary, the above method describes a possibility of extending an applicability of an existing, finished trained reconstruction function to recorded measurement data, which is not present in a desired form which is dedicated to the trained reconstruction function as input data, by this being transferred into the desired, dedicated form by processing the recorded measurement data. With a processing of this type, it is not necessary to use trained functions with at least one neural network, the processing can instead take place in a “conventional” manner In particular, it may be that a processing without using a trained function results in an improved processing result. For instance, unrolled neural networks for reconstructing image data from undersampled recorded MR measurement data are frequently based on SENSE-based signal models, which require coil sensitivity data. An improved unrolling performance can frequently be achieved compared with GRAPPA-based “conventional” processing methods.

FIG. 8 shows a schematic diagram of an inventive image creation facility 15, which is embodied to carry out the inventive method and can be implemented for instance as part of a controller (e.g. controller 9) of a magnetic resonance system (e.g. MR system 1). In particular, an image creation facility 15 can also be used as part of a post-processing pipeline. The image creation facility 15 can also be integrated into other computing facilities or formed hereby.

For realizing functional units, the image creation facility 15 has at least one processor (e.g. processing unit 32 and/or reconstruction unit 42) and at least one memory storage means (memory) 40. Furthermore, the image creation facility 15 has a processing facility 34 which can receive measurement data recorded by way of a first processing interface 31 with a magnetic resonance system. In a processing unit (processor) 32, received, recorded measurement data is processed in processed magnetic resonance data such that the processed magnetic resonance data is present in a form which corresponds to a dedicated form of input data of a reconstruction facility 44 connected to the processing unit 32. In an exemplary embodiment, the processing facility 34 includes processing circuitry configured to perform one or more operations and/or functions of the processing facility 34. One or more components (e.g. processing unit 32) of the processing facility 34 may include processing circuitry configured to perform one or more respective operations and/or functions of the component(s).

The processing of the recorded measurement data into processed magnetic resonance data is carried out e.g. by applying at least one of the methods from the group comprising a regridding method, a slice selection method, in particular a sliceGRAPPA method, a Fourier transform in the image space, a Fourier transform of data present in the image space into the k-space, a PAT method, in particular a GRAPPA or a SENSE method, a correction method and a compressed sensing method.

The processed magnetic resonance data can be provided on a second processing interface 33.

Furthermore, the image creation facility 15 has a reconstruction facility (reconstructor) 44 for creating image data, which can receive processed magnetic resonance data created by way of a first interface 41 with the processing facility 34 as input data. In a reconstruction unit (reconstruction processor) 42, a trained reconstruction function 100 is applied, wherein the output data comprising developing image data can be provided to a second interface 43. In an exemplary embodiment, the reconstruction facility 44 includes processing circuitry configured to perform one or more operations and/or functions of the reconstruction facility 44. One or more components (e.g. reconstruction unit 42) of the reconstruction facility 44 may include processing circuitry configured to perform one or more respective operations and/or functions of the component(s).

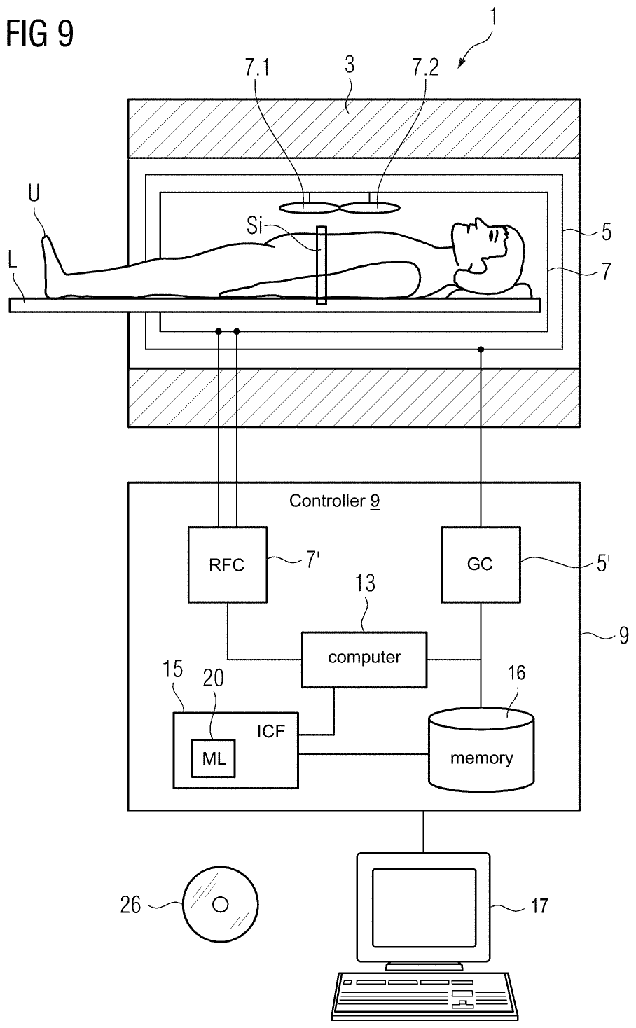

FIG. 9 shows a schematic representation of an inventive magnetic resonance system 1. This comprises a magnet unit 3 for generating the basic magnetic field, a gradient unit 5 for generating the gradient fields, a radio frequency unit 7 for irradiating and receiving radio frequency signals and a control facility (controller) 9 embodied to carry out an inventive method. In an exemplary embodiment, the controller 9 includes processing circuitry configured to perform one or more operations and/or functions of the controller 9. One or more components of the controller 9 may include processing circuitry configured to perform one or more respective operations and/or functions of the component(s). The magnet unit 3, gradient unit 5, and a radio-frequency unit may collectively be referred to as a magnetic resonance (MR) scanner.

In FIG. 9, these subunits of the magnetic resonance system 1 are shown only roughly schematically. In particular, the radio frequency (RF) unit 7 can consist of a plurality of subunits, for example a plurality of coils such as the coils 7.1 and 7.2 shown schematically or more coils which can be configured either only to transmit radio frequency signals or only to receive the triggered radio frequency signals or for both.

In order to examine an examination object U, for example a patient or also a phantom, it can be introduced on a support L into the magnetic resonance system 1, in the measurement volume thereof. The slice or the slab Si shown represents an exemplary target volume of the examination object from which echo signals are to be recorded and captured as measurement data.

The controller 9 may be configured to control the magnetic resonance system 1 and can, in particular, control the gradient unit 5 by means of a gradient control system 5′ and the radio frequency unit 7 by means of a radio frequency transmit/receive controller 7′. The radio frequency unit 7 can herein comprise a plurality of channels on which signals can be transmitted or received.

The radio frequency unit 7 is responsible, together with its radio frequency transmit/receive controller 7′, for the generation and irradiation (transmission) of a radio frequency alternating field for manipulation of the spins in a region to be manipulated (for example, in slices to be measured) of the examination object U. Herein, the center frequency of the radio frequency alternating field, also designated the B1 field, is typically adjusted so that, as far as possible, it lies close to the resonance frequency of the spins to be manipulated. In order to generate the B1 field, in the radio frequency unit 7, currents controlled by means of the radio frequency transmit/receive controller 7′ are applied to the RF coils.

Furthermore, the controller 9 comprises an image creation facility (image generator) 15, which comprises a machine-learning module 20 configured for machine learning, and with which inventive methods can be carried out. The controller 9 is embodied overall to carry out an inventive method. In an exemplary embodiment, the image creation facility 15 includes processing circuitry configured to perform one or more operations and/or functions of the image creation facility 15.

A computer unit (computer) 13 comprised in the controller 9 is configured to carry out/execute (e.g. using one or more processors) all the computation operations necessary for the required measurements and specifications. Intermediate results and results required for this or determined herein can be stored in a memory storage unit 16 of the controller 9. In an exemplary embodiment, the computing unit 13 includes processing circuitry configured to perform one or more operations and/or functions of the computing unit 13. The units shown are herein not necessarily to be understood as physically separate units, but represent merely a subdivision into units of purpose which, however, can also be realized, for example, in fewer, or even only in one, physical unit.

By means of an input/output (I/O) interface 17 of the magnetic resonance system 1, control commands can be passed for example by a user to the magnetic resonance system and/or results from the controller 9 such as, for example, image data can be displayed.

A method described herein can also exist in the form of a computer program product which comprises a program and implements the described method on a controller 9 when said program is executed on the controller 9. An electronically readable data carrier 26 with electronically readable control information stored thereon can also be provided, said control information comprising at least one computer program product as described above and being configured to carry out the method described when the data carrier 26 is used in a controller 9 of a magnetic resonance system 1.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer-implemented method for creating image data from measurement data recorded with a magnetic resonance (MR) system, the method comprising:
providing a trained reconstruction function;
processing the recorded measurement data to generate processed magnetic resonance data, the processed magnetic resonance data being presented in a dedicated form;
applying the provided trained reconstruction function to the magnetic resonance data in the dedicated form, as input data, to determine output data comprising image data; and
providing an electronic output signal representing the output data.

2. The method as claimed in claim 1, wherein the dedicated form of the magnetic resonance data comprises:
specifications for a sampling pattern with which the magnetic resonance data fills k-space,
specifications for an undersampling factor, with which the magnetic resonance data undersamples the k-space,
specifications for a number of slices for which the magnetic resonance data contains information, and/or
specifications for admissible phase errors contained in the magnetic resonance data.

3. The method as claimed in claim 2, wherein the specifications for the sampling pattern with which the magnetic resonance data fills k-space comprise a dimensionality of the filled k-space and/or used k-space trajectories.

4. The method as claimed in claim 1, wherein the processing of recorded measurement data comprises determining a recording form in which the recorded measurement data exists.

5. The method as claimed in claim 4, wherein the processing of recorded measurement data comprises processing steps selected based on the recording form, in which the recorded measurement data exists, the dedicated form of the magnetic resonance data being selected such that the processing steps transfer the recorded measurement data from its recording form into the dedicated form of the magnetic resonance data.

6. The method as claimed in claim 1, wherein the processing of recorded measurement data comprises:
applying a regridding method,
a slice selection method,
a Fourier transform into the image space,
a Fourier transform of data present in the image space into the k-space,
a parallel acquisition techniques (PAT) method, and/or
a correction method.

7. The method as claimed in claim 1, wherein the trained reconstruction function is a variational neural network, an unrolled neural network, and/or a U-shaped neural network; and/or the trained reconstruction function includes a U net.

8. The method as claimed in claim 1, further comprising loading measured reference data, wherein:
the processing of measured measurement data is based on the loaded measured reference data;
the loaded measured reference data has a data consistency assurance included in the trained reconstruction function; and/or
the measured reference data is loaded when the trained reconstruction function receives input data in the form of undersampled magnetic resonance data, in a reconstruction of image data which is included in the trained reconstruction function.

9. A non-transitory computer-readable storage medium with an executable program stored thereon, that when executed, instructs a processor to perform the method of claim 1.

10. An image creation system comprising:
a processing device configured to process measurement data recorded by a magnetic resonance (MR) system into processed magnetic resonance data, which has a form corresponding to a dedicated form of input data of a trained reconstruction function, wherein the processing device includes:
a first processing interface configured to receive the recorded measurement data,
a processor configured to process the received recorded measurement data to transform the received recorded measurement data into a form corresponding to the dedicated form, and
a second processing interface configured to provide the processed magnetic resonance data as an output of the processing device; and
a reconstruction device configured to create image data, the reconstruction device including:
a first interface configured to receive, as input data, the processed magnetic resonance data from the processing device,
a reconstruction processor configured to apply the trained reconstruction function to the input data to determine output data including image data, and
a second interface configured to provide the output data as an output of the reconstruction device.

11. The image creation system as claimed in claim 10, wherein the processor is configured to process the recorded measurement data by applying: a regridding method, a slice selection method, a slice-GeneRalized Autocalibrating Partially Parallel Acquisition (slice-GRAPPA) method, a Fourier transform in image space, a Fourier transform of data present in the image space into k-space, a parallel acquisition techniques (PAT) method, a GeneRalized Autocalibrating Partially Parallel Acquisition (GRAPPA) or a Sensitivity Encoding (SENSE) method, a correction method, and/or a compressed sensing method.

12. The image creation system as claimed in claim 10, wherein the dedicated form of the magnetic resonance data comprises:
specifications for a sampling pattern with which the magnetic resonance data fills k-space,
specifications for an undersampling factor, with which the magnetic resonance data undersamples the k-space,
specifications for a number of slices for which the magnetic resonance data contains information, and/or
specifications for admissible phase errors contained in the magnetic resonance data.

13. The image creation system as claimed in claim 12, wherein the specifications for the sampling pattern with which the magnetic resonance data fills k-space comprise a dimensionality of the filled k-space and/or used k-space trajectories.

14. The image creation system as claimed in claim 10, wherein the processing of recorded measurement data comprises determining a recording form in which the recorded measurement data exists.

15. The image creation system as claimed in claim 14, wherein the processing of recorded measurement data comprises processing steps selected based on a recording form, in which the recorded measurement data exists, the dedicated form of the magnetic resonance data being selected such that the processing steps transfer the recorded measurement data from its recording form into the dedicated form of the magnetic resonance data.

16. A magnetic resonance (MR) system comprising:
a scanner configured to record measurement data; and
the image creation system of claim 10 configured to process the recorded measurement data.

17. A magnetic resonance (MR) system comprising:
a scanner configured to record measurement data; and
a controller configured to:
receive the recorded measurement data from the scanner;
process the recorded measurement data to generate processed magnetic resonance data, the processed magnetic resonance data being present in a dedicated form;
apply a trained reconstruction function to the magnetic resonance data in the dedicated form, as input data, to determine output data comprising image data; and
provide an electronic output signal representing the output data.
